(19) United States
(12) Patent Application Publication
(10) Pub. No.: US 2005/0059206 A1
(43) Pub. Date: Mar. 17, 2005

(54) Integrated circuit devices having barrier layers between upper electrodes and dielectric layers and methods of fabricating the same

(76) Inventors: Jung-hee Chung, Seoul (KR); Jae-hyoung Choi, Kyungki-do (KR); Yun-jung Lee, Seoul (KR); Han-jin Lim, Seoul (KR)

Correspondence Address: MYERS BIGEL SIBLEY & SAJOVEC, PO BOX 37428, RALEIGH, NC, 27627, US

(21) Appl. No.: 10/803,640

(22) Filed: Mar. 18, 2004

(30) Foreign Application Priority Data
Mar. 19, 2003 (KR) 2003-17074

(51) Int. Cl. H01L 21/8242; H01L 27/108; H01L 29/76

(52) U.S. Cl. 438/240; 257/310

(57) ABSTRACT

Integrated circuit devices are provided including an integrated circuit substrate and a capacitor on the integrated circuit substrate. The capacitor includes a lower electrode on the integrated circuit substrate, a dielectric layer on the lower electrode and an upper electrode on the dielectric layer. A barrier layer is provided between the dielectric layer and the upper electrode. The barrier layer includes titanium oxide. Related methods of fabricating integrated circuit devices are also provided.

### RELATED APPLICATION

This application is related to and claims priority from Korean Patent Application No. 2003-17074, filed on Mar. 19, 2003, the disclosure of which is hereby incorporated herein by reference as if set forth in its entirety.

### FIELD OF THE INVENTION

The present invention relates to integrated circuit devices and methods of fabricating the same and, more particularly, to integrated circuit devices having barrier layers and methods of fabricating the same.

### BACKGROUND OF THE INVENTION

Recently, as the size of integrated circuit devices continue to decrease, the area occupied by an integrated circuit device within a chip has also decreased. Furthermore, the size of capacitors used for storing information in, for example, dynamic random access memory (DRAM) devices, may also be reduced, but may have the same or larger capacitances as conventional capacitors. The capacitance of a capacitor may be increased by, for example, increasing the area of a lower electrode, making a dielectric layer of the capacitor thinner, and/or increasing the dielectric constant of the dielectric layer.

The area of a lower electrode can be increased by forming a lower electrode having a 3-dimensional shape, for example, a cylindrical shape or fin shape. However, the fabrication process involved in forming a lower electrode having a 3-dimensional shape may be complicated and the lower electrode may be easily damaged during the process. Furthermore, conventional capacitor dielectric layers include a silicon oxide layer or an oxide-nitride-oxide (ONO) layer, which typically has a thickness of at least 100 Å to obtain a desired capacitance. If the thickness of the silicon oxide layer or the ONO layer is reduced to less than 100 Å to increase the capacitance, the reliability of the dielectric layer may be degraded and a leakage current of the capacitor may increase.

Accordingly, manufacturers of integrated circuit devices may include dielectric layers having higher dielectric constants (k) in the integrated circuit devices to increase the capacitance of the capacitors. These dielectric layers having higher dielectric constants may include a tantalum oxide (Ta₂O₅) layer, a hafnium oxide (HfO₂) layer or the like.

Referring now to FIGS. 1A through 1C, processing steps in the fabrication of metal insulator semiconductor (MIS) capacitors including conventional tantalum oxide dielectric layers will be discussed. Referring to FIG. 1A, a doped polysilicon layer is deposited on an integrated circuit substrate 10. The doped polysilicon layer is patterned to form a lower electrode 20.

As illustrated in FIG. 1B, a tantalum oxide layer (Ta₂O₅) 30 is deposited on the surface of the lower electrode 20 to a thickness of about 60 Å to provide a dielectric layer. The tantalum oxide layer 30 is thermally treated to improve its leakage current and dielectric characteristics. As further illustrated in FIG. 1C, a noble metal layer including, for example, Ruthenium (Ru), Platinum (Pt), Iridium (Ir), Ru oxide, Pt oxide and Ir oxide, is deposited on the tantalum oxide layer 30. The noble metal layer may be formed by supplying a sufficient amount of a noble metal source and oxygen using, for example, chemical vapor deposition (CVD). The noble metal layer may be etched to form an upper electrode 50.

MIS capacitors fabricated using the processing steps discussed with respect to FIGS. 1A through 1C may have a leakage current that varies with temperature. In particular, as illustrated in FIG. 2, when the temperature varies from about 25° C. to about 125° C., the leakage current may increase in proportion to the temperature. Accordingly, defects in the tantalum oxide layer 30 may increase due to the increase in temperature. In other words, oxygen supplied during the deposition of the upper electrode 50, may penetrate into the tantalum oxide layer 30 disposed thereunder and may influence the operation of the capacitor.

Furthermore, voltage sweep characteristics of the integrated circuit device including the tantalum oxide layer 30 may be degraded. As illustrated in FIG. 3, a difference in leakage current was shown in a negative bias region. Since a negative bias is applied to the upper electrode 50, a large amount of leakage current may occur at the interface between the upper electrode 50 and the tantalum oxide layer 30. Thus, capacitors having dielectric layers including a tantalum oxide layer 30 may have leakage currents that experience a high temperature dependency and the voltage sweep characteristics may be degraded.

As discussed above, a hafnium oxide (HfO₂) layer may also be used as a capacitor dielectric layer. However, capacitors using a hafnium oxide layer as the dielectric layer may experience adhesion problems between the hafnium oxide layer and the noble metal upper electrode. Accordingly, the upper electrode may be lifted.

### SUMMARY OF THE INVENTION

Embodiments of the present invention provide integrated circuit devices, such as integrated circuit memory devices, including an integrated circuit substrate and a capacitor on the integrated circuit substrate. The capacitor includes a lower electrode on the integrated circuit substrate, a dielectric layer on the lower electrode and an upper electrode on the dielectric layer. A barrier layer is provided between the dielectric layer and the upper electrode. The barrier layer includes titanium oxide.

In some embodiments of the present invention, the upper electrode may include a noble metal. The noble metal may include at least one of Ruthenium (Ru), Platinum (Pt), Iridium (Ir), Ru oxide, Pt oxide and Ir oxide. The dielectric layer may include tantalum oxide or hafnium oxide and may have a thickness of from about 20 Å to about 50 Å. The barrier layer may have a thickness of from about 10 Å to about 50 Å. The lower electrode may include at least one of a doped polysilicon layer, a noble metal layer and a noble metal oxide layer.

While the present invention is described above primarily with reference integrated circuit devices, methods of fabricating integrated circuit devices are also provided herein.

### BRIEF DESCRIPTION OF THE DRAWINGS

FIGS. 1A through 1C are cross-sections illustrating processing steps in the fabrication of conventional integrated circuit devices.

FIG. 2 is a graph illustrating leakage current versus temperature of conventional integrated circuit devices.

FIG. 3 is a graph illustrating leakage current versus applied voltage in conventional integrated circuit devices.

FIGS. 4A through 4C are cross-sections illustrating processing steps in the fabrication of integrated circuit devices according to some embodiments of the present invention.

FIG. 5 is a graph of leakage current versus temperature in integrated circuit devices according to some embodiments of the present invention.

FIG. 6 is a graph of leakage current versus applied voltage in integrated circuit devices according to some embodiments of the present invention.

FIG. 7 is a cross-section of integrated circuit devices according to further embodiments of the present invention.

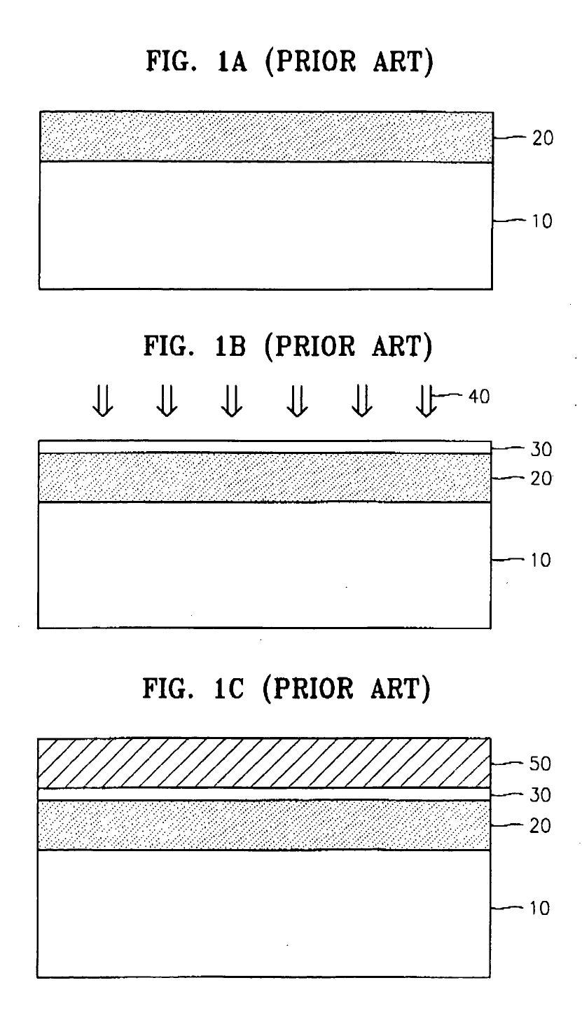

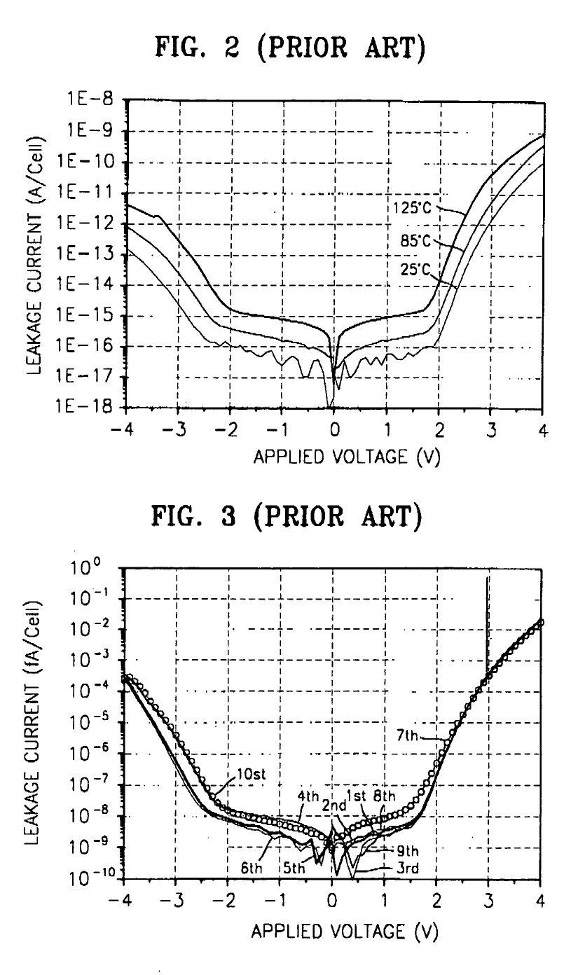

### DETAILED DESCRIPTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. It will be understood that when a layer is referred to as being “on” to another layer, it can be directly on the other layer or intervening layers may also be present. It will be further understood that when a layer is referred to as being “directly on” another layer, no intervening layers may be present. Like numbers refer to like elements throughout.

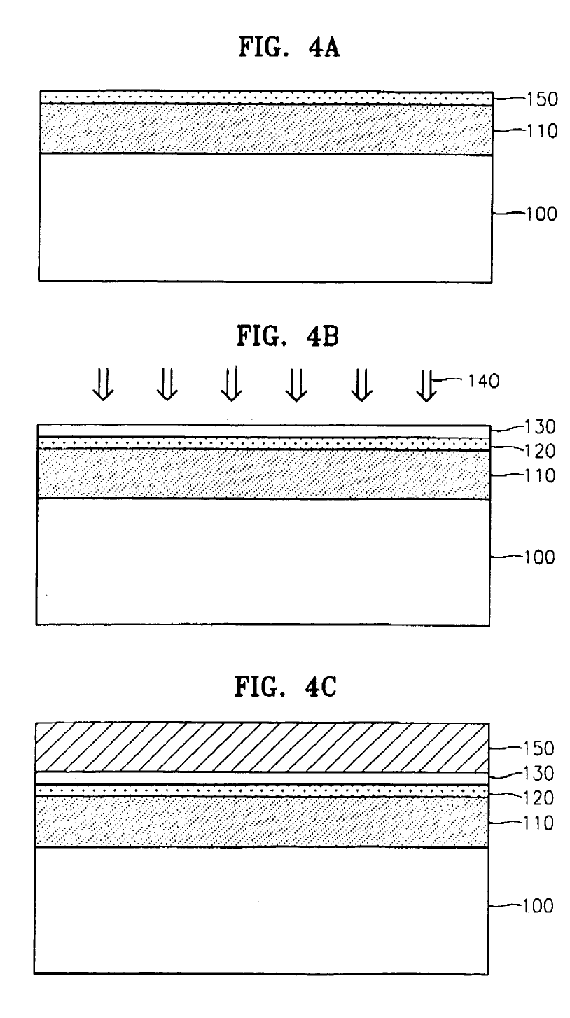

Embodiments of the present invention will be described below with respect to FIGS. 4A through 7. Embodiments of the present invention provide integrated circuit devices including a barrier layer of titanium oxide between a dielectric layer and an upper electrode of a capacitor. The dielectric layer may be, for example, a tantalum oxide (Ta₂O₅) layer, a hafnium oxide (HfO₂) layer or the like. Capacitors including barrier layers according to embodiments of the present invention may reduce the likelihood of the penetration of oxygen into the dielectric layer. Accordingly, defects in the dielectric layer caused by oxygen penetration may be reduced. Furthermore, the inclusion of the barrier layer may also provide a leakage current having low temperature dependency and improved voltage sweep characteristics. Furthermore, dielectric layer including hafnium oxide layer may not experience adhesion problems, as titanium oxide may adhere well to both the hafnium oxide layer and an upper electrode, thus reducing the likelihood that the upper electrode will be lifted.

Referring now to FIG. 4A, an integrated circuit substrate 100 is provided and prepared. In certain embodiments of the present invention, a metal oxide semiconductor (MOS) transistor, an insulating layer, and a bit line (not shown) may be formed on the integrated circuit substrate 100. A first conductive layer is formed on the integrated circuit substrate 100. The first conductive layer may have a thickness of from about 350 Å to about 450 Å. The first conductive layer may include, for example, doped polysilicon, Ruthenium (Ru), Platinum (Pt), Iridium (Ir), or any noble metal oxide layer. The first conductive layer may be patterned to form a lower electrode 10. A first dielectric layer 120 including, for example, tantalum oxide is formed on the lower electrode 110. The tantalum oxide layer 120 may be formed using chemical vapor deposition (CVD). In some embodiments of the present invention, the tantalum oxide layer 120 may be formed using metal organic CVD (MOCVD). The tantalum oxide layer 120 may have thickness of from about 20 Å to about 50 Å, which is thinner than a conventional dielectric layer.

Referring now to FIG. 4B, a second dielectric layer 130 (barrier layer) of titanium oxide (TiO₂) is deposited on the tantalum oxide layer 120. The titanium oxide layer 130 may have a thickness of, for example, from about 10 Å to about 50 Å. As is known to those having skill in the art, the combination of titanium (Ti) and oxygen (O) in the titanium oxide layer 130 is hard and, therefore, the titanium oxide layer 130 can function as a barrier layer during a process of forming an upper electrode.

The titanium oxide layer 130 can be deposited using atomic layer deposition (ALD) at a temperature of from about 200° C. to about 500° C. In particular, a titanium source may be applied to an upper portion of the tantalum oxide layer 120 inside a deposition chamber. The inside of the chamber may be purged and an oxidizer, such as ozone (O₃), may be supplied to the surface of the resultant structure. Finally, the inside of the chamber may be purged. The steps may be repeated one or more times.

Furthermore, the presence of the titanium oxide layer 130, which has a high dielectric constant (k) of about 60, may improve the dielectric characteristics of the capacitor. However, although the titanium oxide layer 130 may function as a reliable barrier layer, it may also have a high leakage current.

The titanium oxide layer 130 and the tantalum oxide layer 120 are thermally treated 140 to improve the dielectric constants of the titanium oxide layer 130 and the tantalum oxide layer 120. In particular, the tantalum oxide layer 120 and the titanium oxide layer 130 may be deposited in an amorphous state and, therefore, the dielectric characteristics of the tantalum oxide layer 120 and the titanium oxide layer 130 may be poor. If the tantalum oxide layer 120 and the titanium oxide layer 130 are crystallized, the dielectric constants may be improved, however, a dielectric layer having a low dielectric constant may be generated between the tantalum oxide layer 120 and the lower electrode 110. Accordingly, the dielectric constant may decrease and the leakage current may increase. In some embodiments of the present invention, the titanium oxide layer 130 and the tantalum oxide layer 120 are thermally treated 140 at a temperature lower than the inherent crystallized temperature (750° C.) of the tantalum oxide layer 120, for example, from about 500° C. to about 700° C., for from about 20 to about 40 minutes such that the dielectric constant increases and the leakage current decreases.

As illustrated in FIG. 4C, a second conductive layer is deposited on the titanium oxide layer 130 to a thickness of from about 250 Å to about 350 Å. The second conductive layer may be formed of a noble metal, such as Ru, Pt, and/or Ir, or any oxide thereof. The conductive layer may be formed using CVD by supplying large amounts of, for example, a Ru source and oxygen. Oxygen supplied during deposition of Ru may penetrate into the tantalum oxide layer 120. However, according to embodiments of the present invention, the titanium oxide layer 130 can function as a barrier to the penetration of oxygen.

The second conductive layer is patterned to form an upper electrode 150. According to some embodiments of the present invention, the upper electrode 150 may not be lifted as the adhesion of the titanium oxide layer 130 with the upper electrode 150 formed of Ru is reliable. The upper electrode 150 may be cured in an oxygen atmosphere at a temperature of from about 350° C. to about 450° C. for about 30 minutes.

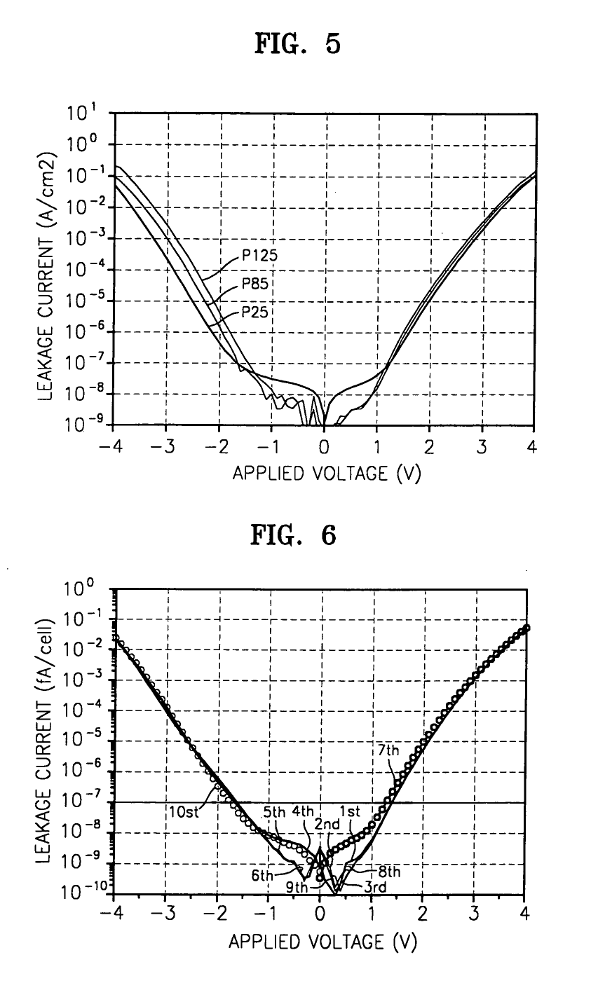

Referring now to FIG. 5, when the titanium oxide layer 130, a dielectric layer, is positioned between the tantalum oxide layer 120 and the upper electrode 150 the leakage current may be maintained at a relatively constant level even when the temperature is varied. As illustrated in FIG. 6, even if a voltage sweep is applied several times, the leakage current may hardly vary with applied voltage.

According to some embodiments the present invention, the titanium oxide layer 130 is positioned between a tantalum oxide layer 120 and the noble metal upper electrode 150, thus, the likelihood that supplied oxygen will penetrate into the tantalum oxide layer 120 may be reduced during deposition of metal upper electrode 150. Accordingly, defects resulting from oxygen penetration may be reduced in the tantalum oxide layer 120. Furthermore, in certain embodiments of the present invention, the leakage current may be less dependent on temperature and voltage sweep characteristics may be improved.

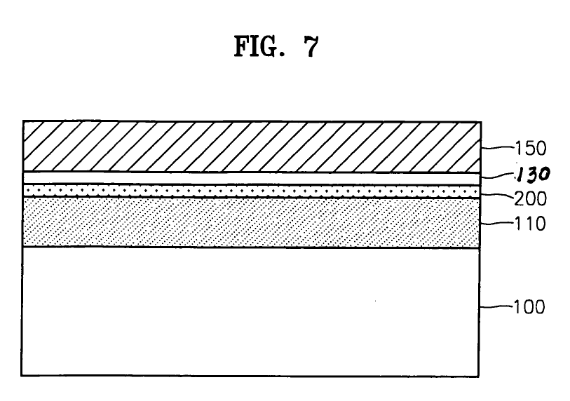

Referring now to FIG. 7, a cross-sectional view of an integrated circuit device according to further embodiments of the present invention will be discussed. Like reference numerals refer to like elements discussed above with respect to FIGS. 4A through 6 above and, therefore, these elements will not be discussed in detail herein. As illustrated in FIG. 7, a dielectric layer having a dielectric constant similar to that of a tantalum oxide layer, for example, a hafnium oxide (HfO₂) layer 200, is formed on a lower electrode 110. The hafnium oxide layer 200 may be deposited using ALD. The hafnium oxide layer may have a thickness of from about 20 Å to about 50 Å. A titanium oxide layer 130 may be deposited on the hafnium oxide layer 200 as discussed above with respect to FIGS. 4A through 4C.

The titanium oxide layer 130 and the hafnium oxide layer 200 are thermally treated at a temperature lower than a crystallization temperature, and an upper electrode 150 is formed on the titanium oxide layer 130. As discussed above, the upper electrode 150 is formed using a noble metal, for example, Ru.

Accordingly, adhesion of the titanium oxide layer 130 with the upper electrode 150 formed of, for example, Ru is reliable. Thus, even if the hafnium oxide layer 200 is used as a dielectric layer, the likelihood that the upper electrode 150 will be lifted may be reduced.

As briefly discussed above with respect to FIGS. 4A through 7, a titanium oxide layer may be positioned between a tantalum oxide layer, a hafnium oxide layer or the like and an upper electrode. Thus, the likelihood that oxygen will penetrate into the tantalum oxide layer or the hafnium oxide layer may be reduced during deposition of metal upper electrode. Accordingly, defects in the dielectric layer may be reduced, the leakage current may be less temperature dependent and voltage sweep characteristics may be improved. Furthermore, hafnium oxide may be used in dielectric layers according to some embodiments of the present invention due to the presence of the titanium oxide layer. In particular, the adhesion of a titanium oxide layer with both the hafnium oxide layer and an upper electrode is reliable, thus the likelihood that the upper electrode will be lifted may be reduced.

In the drawings and specification, there have been disclosed typical preferred embodiments of the invention and, although specific terms are employed, they are used in a generic and descriptive sense only and not for purposes of limitation, the scope of the invention being set forth in the following claims.

1. An integrated circuit device comprising:
an integrated circuit substrate;
a capacitor on the integrated circuit substrate, the capacitor including a lower electrode, a dielectric layer on the lower electrode and an upper electrode on the dielectric layer; and
a barrier layer between the dielectric layer and the upper electrode, the barrier layer including titanium oxide and the dielectric layer including tantalum oxide and/or hafnium oxide.

2. The integrated circuit device of claim 1, wherein the upper electrode comprises a noble metal.

3. The integrated circuit device of claim 3, wherein the dielectric layer has a thickness of from about 20 Å to about 50 Å.

4. The integrated circuit device of claim 1, wherein the barrier layer has a thickness of from about 10 Å to about 50 Å.

5. The integrated circuit device of claim 1, wherein the lower electrode comprises at least one of a doped polysilicon layer, a noble metal layer and a noble metal oxide layer.

6. The integrated circuit device of claim 1, wherein the upper electrode comprises at least one of Ruthenium (Ru), Platinum (Pt), Iridium (Ir), Ru oxide, Pt oxide and Ir oxide.

7. A method of forming an integrated circuit device comprising:
forming a lower electrode of a capacitor on an integrated circuit substrate;
forming a dielectric layer on the lower electrode, the dielectric layer including tantalum oxide and/or hafnium oxide;
forming a barrier layer on the dielectric layer and the upper electrode, the barrier layer including a titanium oxide layer; and
forming an upper electrode on the dielectric layer.

8. The method of claim 7, wherein forming the barrier layer and the upper electrode further comprise:
forming the titanium oxide layer on the dielectric layer;
thermally treating the dielectric layer and the titanium oxide layer; and
forming an upper electrode on the titanium oxide layer, the upper electrode including a noble metal.

9. The method of claim 7, wherein forming the dielectric layer comprises forming a tantalum oxide layer on the lower electrode by chemical vapor deposition (CVD).

10. The method of claim 7, wherein forming the dielectric layer comprises forming a hafnium oxide layer on the lower electrode by atomic layer deposition (ALD).

11. The method of claim 7, wherein forming the dielectric layer comprises forming the dielectric layer having a thickness of from about 20 Å to about 50 Å.

12. The method of claim 8, wherein forming the titanium oxide layer comprises forming the titanium oxide layer by atomic layer deposition (ALD).

13. The method of claim 12, wherein forming the titanium oxide layer further comprises:
supplying a titanium source to an upper portion of the dielectric layer in a chamber;
purging an inside of the chamber;
supplying an oxidizer;
purging the inside of the chamber; and
repeating the supplying a titanium source, purging, supplying an oxidizer and the purging at least once.

14. The method of claim 12, wherein forming the titanium oxide layer comprises forming the titanium oxide layer to have a thickness of from about 10 Å to about 50 Å.

15. The method of claim 7, wherein forming the lower electrode comprises forming the lower electrode of at least one of a doped polysilicon layer, a noble metal layer, and a noble metal oxide layer.

16. The method of claim 7 wherein forming the upper electrode comprises forming the upper electrode of at least one of Ruthenium (Ru), Platinum (Pt), Iridium (Ir), Ru oxide, Pt oxide and Ir oxide.

17. The method of claim 8, wherein the thermally treating comprises thermally treating the dielectric layer and the titanium oxide layer at a temperature lower than a crystallization temperature of the dielectric layer.

18. The method of claim 8, wherein forming the upper electrode is followed by curing the resultant structure in an oxygen atmosphere at a temperature of from about 350° C. to about 450° C.

19. A method of fabricating an integrated circuit device, the method comprising:
forming a lower electrode on an integrated circuit substrate;
depositing a tantalum oxide layer on the lower electrode;
depositing a titanium oxide layer for a barrier layer on the tantalum oxide layer by atomic layer deposition (ALD);
thermally treating the titanium oxide layer and the tantalum oxide layer;
forming an upper electrode including Ruthenium (Ru) on the titanium oxide layer; and
curing the upper electrode.

20. A method of fabricating an integrated circuit device, the method comprising:
forming a lower electrode on an integrated circuit substrate;
depositing a hafnium oxide layer on the lower electrode;
depositing a titanium oxide layer for a barrier layer on the hafnium oxide layer;
thermally treating the titanium oxide layer and the hafnium oxide layer;
forming an upper electrode of Ruthenium (RLI) on the titanium oxide layer; and
curing the resultant structure.
